(19) United States
(12) Patent Application Publication
(10) Pub. No.: US 2026/0011479 A1
(43) Pub. Date: Jan. 8, 2026

(54) PLANAR TRANSFORMER AND POWER SUPPLY DEVICE WITH SAME

(71) Applicant: Delta Electronics, Inc., Taoyuan City (TW)

(72) Inventors: Guo-Ning Chen, Taoyuan City (TW); Chien-An Lai, Taoyuan City (TW); Shih-Hung Lo, Taoyuan City (TW); Wei-Lin Chen, Taoyuan City (TW)

(21) Appl. No.: 19/209,535

(22) Filed: May 15, 2025

Related U.S. Application Data
(60) Provisional application No. 63/668,507, filed on Jul. 8, 2024.

(30) Foreign Application Priority Data
Feb. 10, 2025 (CN) 202510144663.9

(51) Int. Cl. H01F 27/28; H01F 27/24; H02M 7/00; H05K 7/20

(52) U.S. Cl. CPC H01F 27/28; H01F 27/24; H02M 7/003; H05K 7/20927

(57) ABSTRACT

A planar transformer and a power supply device with the planar transformer are provided. The planar transformer includes a primary winding assembly, a secondary winding assembly and a magnetic core assembly. The primary winding assembly includes at least one primary winding unit. Each of the at least one primary winding unit includes a printed circuit board and a first conductive sheet. The first conductive sheet is embedded within the printed circuit board. The secondary winding assembly includes at least one secondary winding unit. The magnetic core assembly includes at least one magnetic core. In addition, at least a portion of the at least one primary winding unit and at least a portion of the at least one secondary winding unit are enclosed by the magnetic core assembly.

### CROSS-REFERENCE TO RELATED APPLICATIONS

This application claims benefit of U.S. Provisional Application No. 63/668,507, filed on Jul. 8, 2024, and also claims priority to China patent application No. 202510144663.9 filed on Feb. 10, 2025. The entire contents of the above-mentioned patent applications are incorporated herein by reference for all purposes.

### FIELD OF THE INVENTION

The present disclosure relates to a transformer, and more particularly to a planar transformer and a power supply device with the planar transformer.

### BACKGROUND OF THE INVENTION

Generally, the conventional transformer adopts a winding type design. For the insulation purpose, a triple-layer insulated wire or a double-layer insulated tape are used to wrap the region between the primary winding and the secondary winding. As such, the manufacturing process becomes complex, and the parasitic parameters of the transformer cannot achieve good consistency. In addition, in high-power applications, the outlet terminals of the transformer cannot be effectively fixed on the bobbin. Consequently, the difficulty of assembling the transformer is increased.

For effectively solving the problems of the conventional winding-type transformers, planar transformers are introduced into the market. Generally, the planar transformer possesses a thinner size, excellent repeatability and consistency, and an easily modularized design.

Consequently, the planar transformer can be manufactured and assembled more easily. However, since the conventional planar transformers use a printed circuit board winding design (i.e., a winding assembly where traces are formed on the printed circuit board), the copper foil of the printed circuit is suffered from a thickness limitation. Due to the thickness limitation, the equivalent resistance is high, the current carrying capacity is low, and the copper loss is high. Consequently, the use of the conventional planar transformer is limited in high-power applications.

Therefore, there is a need of providing an improved planar transformer and a power supply device with the planar transformer to obviate the drawbacks encountered from the prior arts.

### SUMMARY OF THE INVENTION

The present disclosure provides a planar transformer and a power supply device with the planar transformer. Due to the structural design of the planar transformer of the present disclosure, the problems of conventional planar transformers are solved. Consequently, the equivalent resistance is reduced, the current handling capacity is increased, and the copper loss is reduced. In other words, the high-power applications of the planar transformer will be expanded.

In accordance with an aspect of the present disclosure, a planar transformer is provided. The planar transformer includes a primary winding assembly, a secondary winding assembly and a magnetic core assembly. The primary winding assembly includes at least one primary winding unit. Each of the at least one primary winding unit includes a printed circuit board and a first conductive sheet. The first conductive sheet is embedded within the printed circuit board. The secondary winding assembly includes at least one secondary winding unit. The magnetic core assembly includes at least one magnetic core. In addition, at least a portion of the at least one primary winding unit and at least a portion of the at least one secondary winding unit are enclosed by the magnetic core assembly.

In accordance with an aspect of the present disclosure, a power supply device is provided. The power supply device includes an input terminal, an output terminal, a power factor correction device, a first planar transformer, a second planar transformer, a main circuit board, a primary winding connection board, a secondary winding connection board, a water-cooling heat dissipation device, an inverter device, a first housing and a second housing. The power factor correction device receives a three-phase AC power through the input terminal. Each of the first planar transformer and the second planar transformer includes a primary winding assembly, a secondary winding assembly and a magnetic core assembly. The primary winding assembly includes at least one primary winding unit. The secondary winding assembly includes at least one secondary winding unit. The magnetic core assembly includes at least one magnetic core. Each of the at least one primary winding unit includes a printed circuit board and a first conductive sheet. The first conductive sheet is embedded within the printed circuit board. In addition, at least a portion of the at least one primary winding unit and at least a portion of the at least one secondary winding unit are enclosed by the magnetic core assembly. The primary winding connection board is connected with the at least one primary winding unit of the first planar transformer and the at least one primary winding unit of the second planar transformer. The secondary winding connection board is connected with the at least one secondary winding unit of the first planar transformer and the at least one secondary winding unit of the second planar transformer. The inverter device outputs an output DC power to the output terminal. The main circuit board, the first planar transformer, the second planar transformer, the water-cooling heat dissipation device, the power factor correction device and the inverter device are covered by the first housing and the second housing.

### BRIEF DESCRIPTION OF THE DRAWINGS

FIG. 1 is a schematic perspective view illustrating a planar transformer of the present disclosure;

FIG. 2 is a schematic exploded view illustrating the planar transformer shown in FIG. 1;

FIG. 3 is a schematic perspective view illustrating one of the primary winding units of the planar transformer shown in FIG. 1;

FIG. 4 is a schematic perspective view illustrating the assembled structure of the planar transformer of FIG. 1 and at least one connection board;

FIG. 5 is a schematic side and perspective view illustrating the planar transformer as shown in FIG. 1;

FIG. 6 is a schematic side and perspective view illustrating the structure of a conventional planar transformer;

FIG. 7 is a schematic perspective view illustrating the assembled structure of a power supply device according to an embodiment of the present disclosure;

FIG. 8 is a schematic exploded view illustrating the power supply device as shown in FIG. 7;

FIG. 9 is a schematic perspective view illustrating the combination of two planar transformers of FIG. 7, a first winding connection board and a second winding connection board;

FIG. 10 is a schematic perspective view illustrating the relationship between the planar transformer of FIG. 7, a primary winding connection board and a secondary winding connection board;

FIG. 11 schematically illustrates a first exemplary structure of the primary winding assembly and the secondary winding assembly of the planar transformer and a winding method thereof;

FIG. 12 schematically illustrates a second exemplary structure of the primary winding assembly and the secondary winding assembly of the planar transformer and a winding method thereof; and

FIG. 13 schematically illustrates a third exemplary structure of the primary winding assembly and the secondary winding assembly of the planar transformer and a winding method thereof.

### DETAILED DESCRIPTION OF THE PREFERRED EMBODIMENT

The present disclosure will now be described more specifically with reference to the following embodiments. It is to be noted that the following descriptions of preferred embodiments of the present disclosure are presented herein for purpose of illustration and description only. It is not intended to be exhaustive or to be limited to the precise form disclosed.

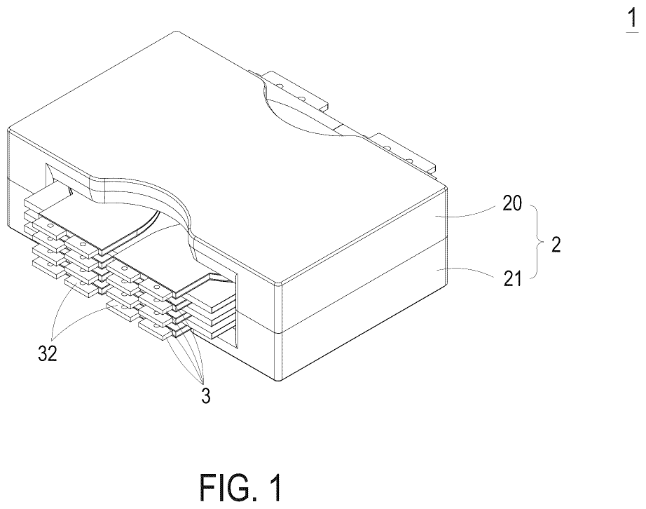

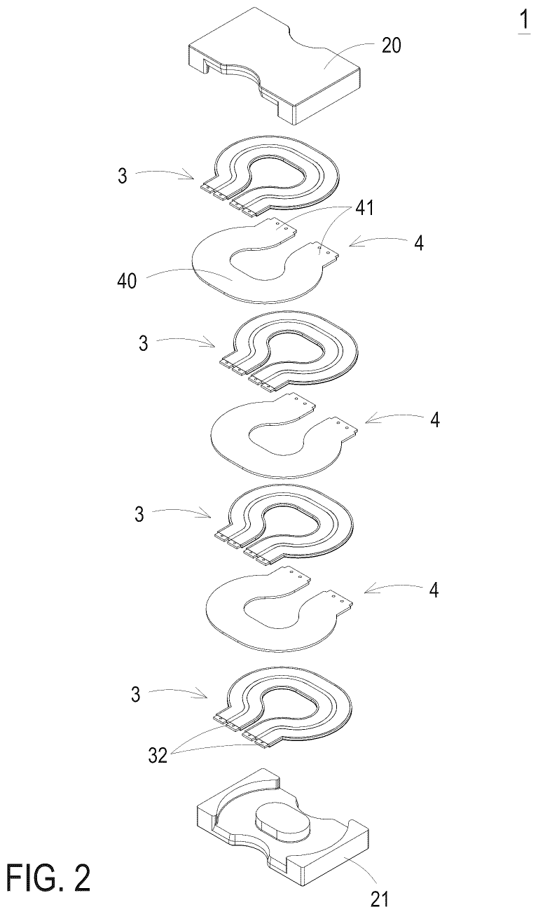

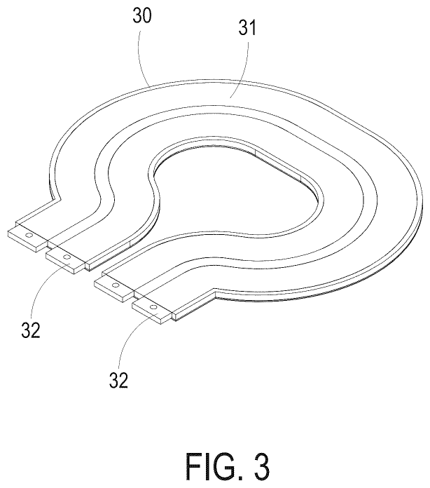

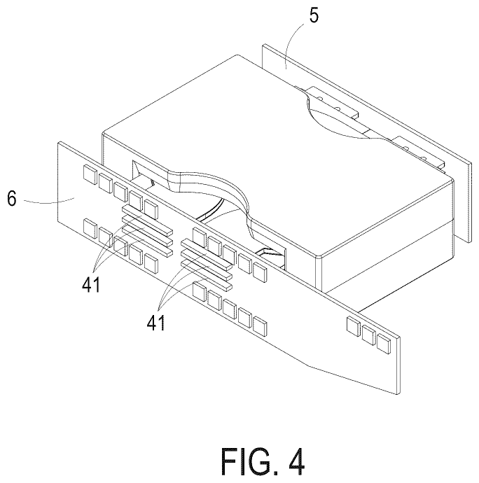

Please refer to FIGS. 1, 2, 3 and 4. FIG. 1 is a schematic perspective view illustrating a planar transformer of the present disclosure. FIG. 2 is a schematic exploded view illustrating the planar transformer shown in FIG. 1. FIG. 3 is a schematic perspective view illustrating one of the primary winding units of the planar transformer shown in FIG. 1. FIG. 4 is a schematic perspective view illustrating the assembled structure of the planar transformer of FIG. 1 and at least one connection board. The planar transformer 1 includes a magnetic core assembly 2, a primary winding assembly and a secondary winding assembly.

The primary winding assembly includes at least one primary winding unit 3. Each of the at least one primary winding unit 3 includes a printed circuit board 30 and a first conductive sheet 31. The first conductive sheet 31 is embedded within the printed circuit board 30. That is, the first conductive sheet 31 is covered by the printed circuit board 30.

The secondary winding assembly includes at least one secondary winding unit 4.

The magnetic core assembly 2 includes at least one magnetic core. As shown in FIG. 1, the magnetic core assembly 2 includes two magnetic cores 20 and 21. The two magnetic cores 20 and 21 are located on two opposite outer sides of the planar transformer 1. In addition, at least a portion of the at least one primary winding unit 3 and at least a portion of the at least one secondary winding unit 4 are enclosed by the two magnetic cores 20 and 21 collaboratively. Preferably but not exclusively, the magnetic cores 20 and 21 are E-shaped or U-shaped magnetic cores.

In an embodiment, the primary winding assembly includes a plurality of primary winding units 3. For example, the primary winding assembly includes four primary winding units 3. Preferably, the first conductive sheet 31 has an annular, rectangular or polygonal sheet-like structure with a notch. The first conductive sheet 31 is made of a conductive material such as metallic material. For example, the first conductive sheet 31 is a metal plate, and preferably a copper plate.

In an embodiment, the primary winding assembly includes a plurality of first conductive sheet 31. Each first conductive sheet 31 includes two first outlet terminals 32. The first conductive sheets 31 of the plurality of primary winding units 3 are arranged in the same direction. The first outlet terminals 32 of the first conductive sheets 31 of the plurality of primary winding units 3 are located at a first side of the planar transformer 1. Preferably but not exclusively, each of the first conductive sheets 31 has two turns. In some embodiments, the first conductive sheets 31 of the plurality of primary winding units 3 are connected with each other in series.

In an embodiment, the secondary winding assembly includes a plurality of secondary winding units 4. For example, the secondary winding assembly includes three secondary winding units 4. Each secondary winding unit 4 includes a second conductive sheet 40. The second conductive sheet 40 has an annular, rectangular or polygonal sheet-like structure with a notch. The second conductive sheet 40 is made of a conductive material such as a metallic material. For example, the second conductive sheet 40 is a metal plate, and preferably a copper plate.

Furthermore, each second conductive sheet 40 includes two second outlet terminals 41. The second conductive sheets 40 of the plurality of secondary winding units 4 are arranged in a same direction. In addition, the second outlet terminals 41 of the second conductive sheets 40 of the plurality of secondary winding units 4 are located at a second side of the planar transformer 1. The first side and the second side are two opposite sides of the planar transformer 1.

Especially, one secondary winding unit 4 is arranged between every two adjacent primary winding units 3. Consequently, the first conductive sheets 31 of the two adjacent primary winding units 3 and the second conductive sheet 40 of the secondary winding unit 4 are insulated from each other through the printed circuit boards 30 of the two adjacent primary winding units 3.

In some embodiments, as shown in FIG. 4, the first outlet terminals 32 are inserted into the primary winding connection board 5, and the primary-side electronic devices are placed on the primary winding connection board 5. The second outlet terminals 41 are inserted into the secondary winding connection board 6. The secondary-side electronic devices are placed on the secondary winding connection board 6.

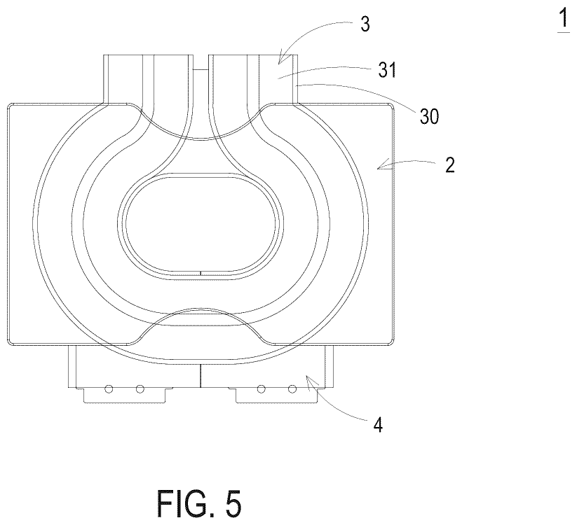

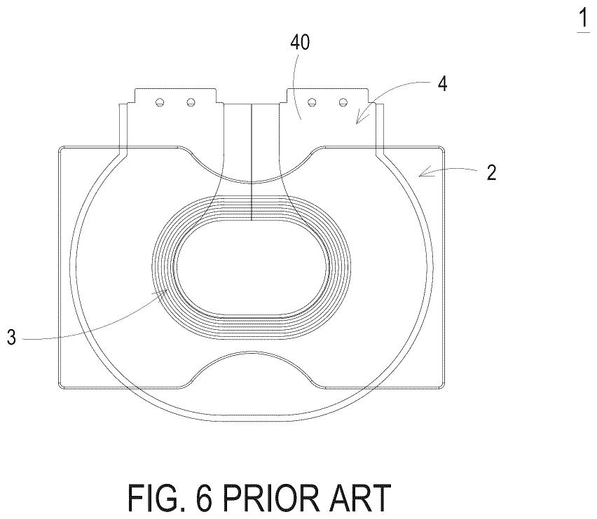

Please refer to FIGS. 5 and 6 and also refer to FIGS. 1, 2, 3 and 4. FIG. 5 is a schematic side and perspective view illustrating the planar transformer as shown in FIG. 1. FIG. 6 is a schematic side and perspective view illustrating the structure of a conventional planar transformer. In the embodiment of the present disclosure, the primary winding unit 3 of the planar transformer 1 includes the first conductive sheet 31, and the first conductive sheet 31 is covered by the printed circuit board 30. Consequently, the equivalent cross-sectional area of the primary winding assembly of the planar transformer 1 can be maximized. In this way, the DC resistance is reduced, and the efficiency of the planar transformer 1 is improved. For example, the thickness of the first conductive sheet 31 of the primary winding unit 3 in the planar transformer 1 is 44 ounces. Generally, the thickness of the printed circuit board winding of the conventional planar transformer is between 2 oz to 4 oz. In other words, the thickness of the primary winding assembly of the present disclosure is 11 to 22 times greater than the thickness of the primary winding assembly of the conventional planar transformer. Consequently, as shown in FIGS. 5 and 6, the winding space utilization of the first conductive sheet 31 of the primary winding unit 3 of the present disclosure is larger, and the space utilization of the printed circuit board winding in conventional planar transformers is lower. In addition, the equivalent cross-sectional area of the primary winding assembly of the planar transformer of the present disclosure is greater than the equivalent cross-sectional area of the printed circuit board winding of the conventional planar transformer. Consequently, the current density of the planar transformer 1 of the present disclosure is lower.

Please refer to Table 1 and Table 2. Table 1 illustrates the comparison of the DC resistance between the planar transformer 1 of the present disclosure and a conventional planar transformer. Table 2 illustrates the comparison of the core loss, copper loss, and total loss between the planar transformer 1 of the present disclosure and the conventional planar transformer. As shown in Table 1, the DC resistance of the conventional planar transformer is 6.7 times that of the planar transformer 1 of the present disclosure, indicating that the planar transformer 1 has lower DC resistance. Moreover, as shown in Table 2, the core loss, copper loss, and total loss of the planar transformer 1 of the present disclosure under the full load operation are lower than those of the conventional planar transformer.

TABLE 1

DC resistance (mΩ)

| | Primary winding | Secondary winding |
|---|---|---|
| | (Serial connection) | Parallel connection) |
| Present planar | 2.56 | 2.35E−02 |
| transformer | | |
| Conventional planar | 17.26 | 2.35E−02 |
| transformer | | |

TABLE 2

| | Magnetic | Copper loss | | Total loss |
|---|---|---|---|---|
| Full load operation | loss (W) | AC loss (W) | DC loss (W) | (W) |
| Present planar | 11.04 | 11.6 | 1.95 | 24.58 |
| transformer | | | | |
| Conventional planar | 14.70 | 10.18 | 11.56 | 36.43 |
| transformer | | | | |

From the above descriptions, the planar transformer 1 of the present disclosure also has the advantages of conventional planar transformers. For example, the planar transformer 1 of the present disclosure has excellent repeatability and consistency, and is easy to produce. Furthermore, in the primary winding unit 3, the first conductive sheet 31 is covered by the printed circuit board 30. Consequently, the problems of high losses and limited power capacity in conventional planar transformers due to insufficient copper foil thickness can be solved. Moreover, due to the structural design of the first outlet terminal 32 and the second outlet terminal 41 of the planar transformer 1, the planar transformer 1 and a power semiconductor module are suitably integrated into a DC-DC converter power module. Consequently, the overall size is reduced. The modular design of the planar transformer 1 also simplifies the assembling process. Furthermore, the first conductive sheets 31 of every two adjacent primary winding units 3 and the second conductive sheet 40 of the secondary winding unit 4 are insulated from each other through the printed circuit boards 30 of the two adjacent primary winding units 3. Consequently, the manufacturing process is simplified. Moreover, since the cross-sectional area of the primary winding assembly of the planar transformer can be maximized, the winding space utilization is improved, and the power density is increased. Since the thickness of the first conductive sheet 31 is also increased, the DC resistance is reduced, and the operating efficiency of the planar transformer 1 is improved.

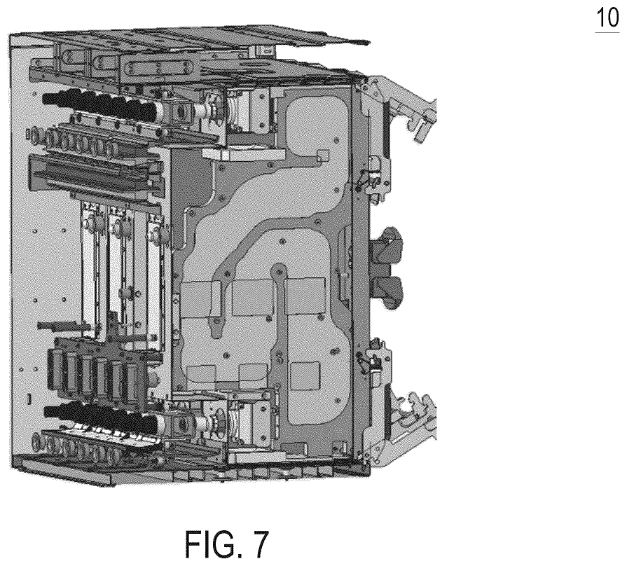

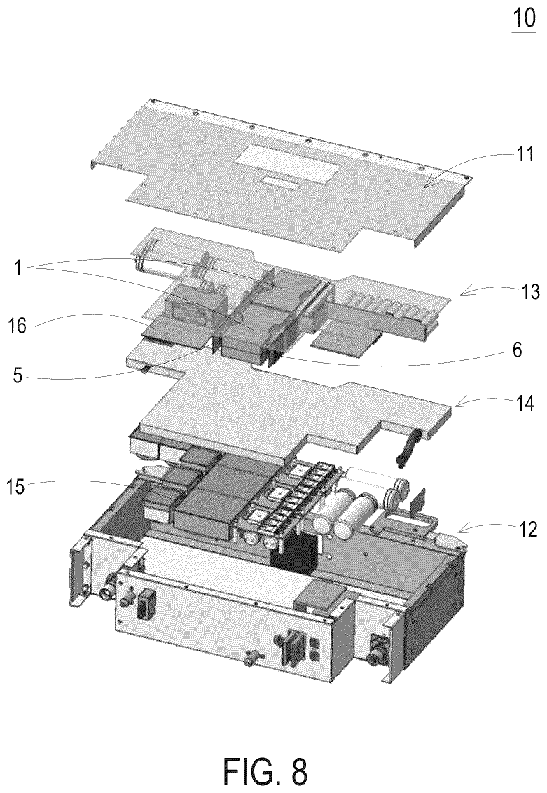

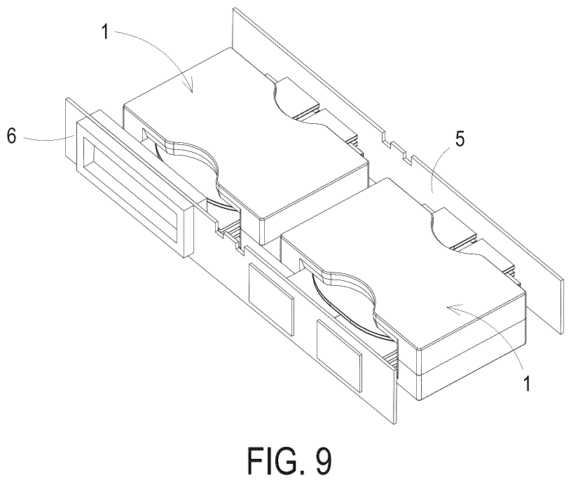

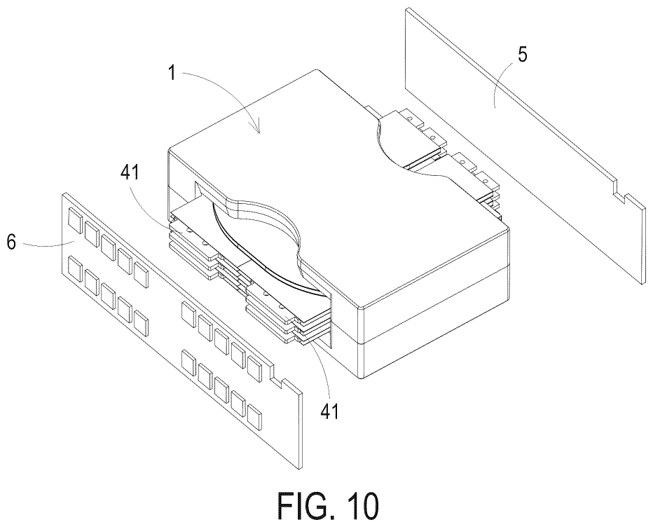

Please refer to FIGS. 7, 8, 9 and 10. FIG. 7 is a schematic perspective view illustrating the assembled structure of a power supply device according to an embodiment of the present disclosure. FIG. 8 is a schematic exploded view illustrating the power supply device as shown in FIG. 7. FIG. 9 is a schematic perspective view illustrating the combination of two planar transformers of FIG. 7, a first winding connection board and a second winding connection board. FIG. 10 is a schematic perspective view illustrating the relationship between the planar transformer of FIG. 7, a primary winding connection board and a secondary winding connection board. In an embodiment, the power supply device 10 is applied to an artificial intelligence server. The input terminal of the power supply device 10 receives a three-phase AC power source. The output terminal of the power supply device 10 outputs a 48-volt DC power. Preferably but not exclusively, the power supply 10 is equipped with a water cooling mechanism for heat dissipation. The power supply device 10 further includes a first housing 11, a second housing 12, a primary winding connection board 5, a secondary winding connection board 6, a main circuit board 13, two planar transformers 1, a water-cooling heat dissipation device 14, a power factor correction device 15 and an inverter device 16. Each of the two planar transformers has the structure similar to the planar transformer as shown in FIG. 1, and not redundantly described herein.

The primary winding connection board 5, the secondary winding connection board 6, the main circuit board 13, the two planar transformers 1, the water-cooling heat dissipation device 14, the power factor correction device 15 and the inverter device 16 are covered by the first housing 11 and second housing 12 collaboratively. The first outlet terminals 32 of the primary winding units 3 of the two planar transformers 1 are inserted into the primary winding connection board 5. Consequently, the primary winding units 3 are assembled with the primary winding connection board 5. The first conductive sheets 31 of the primary winding units 3 are electrically connected to the primary winding connection board 5 in series or in parallel. Consequently, the complexity of the manufacturing the primary winding assembly of the planar transformer 1 can be reduced. The second outlet terminals 41 of the secondary winding units 4 of the two planar transformers 1 are inserted into the secondary winding connection board 6. Since the secondary winding units 4 are connected to the secondary winding connection board 6, the current transmission path is shortened, and the power loss is also reduced. Furthermore, the primary winding connection board 5 and the secondary winding connection board 6 are assembled with the main circuit board 13. The power factor correction device 15 is connected to output terminal of the power supply device 10 to receive the three-phase AC power. The inverter device 16 is connected with the output terminal of the power supply device 10 and outputs the output DC power to the output terminal. The water-cooling heat dissipation device 14 is used to remove heat from the power supply device 10 in a water cooling manner.

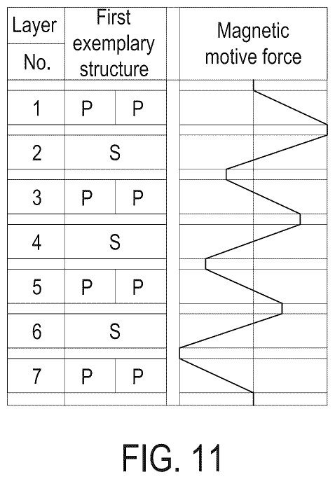

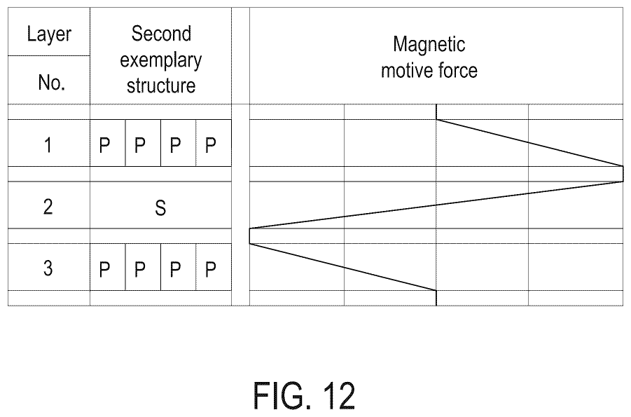

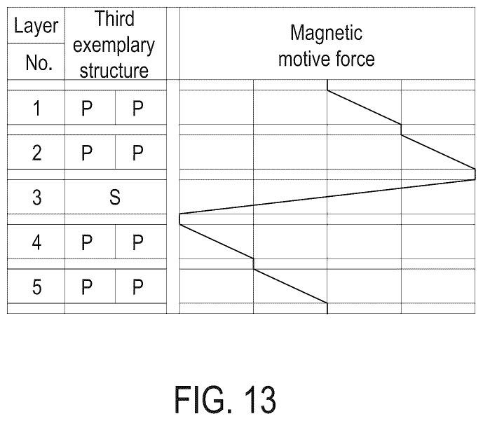

Please refer to FIGS. 11, 12 and 13 and also refer to FIGS. 1, 2, 3 and 4. FIG. 11 schematically illustrates a first exemplary structure of the primary winding assembly and the secondary winding assembly of the planar transformer and a winding method thereof. FIG. 12 schematically illustrates a second exemplary structure of the primary winding assembly and the secondary winding assembly of the planar transformer and a winding method thereof. FIG. 13 schematically illustrates a third exemplary structure of the primary winding assembly and the secondary winding assembly of the planar transformer and a winding method thereof. By adjusting the structure and the winding method of the primary winding assembly and the secondary winding assembly of the planar transformer 1 of the present disclosure, the magnetic motive force (MMF) and the parasitic stray capacitance can be adjusted.

In FIG. 11, the planar transformer 1 has a seven-layer structure. That is, the primary winding assembly includes four primary winding units 3, and the secondary winding assembly includes three secondary winding units 4. Moreover, the four primary winding units 3 are respectively formed in a first layer, a third layer, a fifth layer and a seventh layer of the seven-layer structure, and the three secondary winding units 4 are respectively formed in a second layer, a fourth layer and a sixth layer of the seven-layer structure. Each of the first conductive sheets 31 of the four primary winding units 3 has two turns (each layer is marked with two P symbols), and each of the second conductive sheets 40 of the three secondary winding units 4 has one turn (each layer is marked with one S symbol). Due to this structural design, the magnetic motive force of the planar transformer 1 ultimately achieves a positive and negative balance.

In FIG. 12, the planar transformer 1 has a three-layer structure. That is, the primary winding assembly includes two primary winding units 3, and the secondary winding assembly includes one secondary winding unit 4. Moreover, the two primary winding units 3 are respectively formed in a first layer and a third layer of the three-layer structure, and the secondary winding unit 4 is formed in a second layer of the three-layer structure. Each of the first conductive sheets 31 of the four primary winding units 3 has four turns (each layer is marked with four P symbols), and the second conductive sheet 40 of the secondary winding unit 4 has one turn (this layer is marked with one S symbol). Due to this structural design, the magnetic motive force trend of the planar transformer 1 in FIG. 12 becomes symmetrical when compared with the magnetic motive force of the planar transformer 1 of FIG. 11. In addition, the parasitic stray capacitance is reduced.

In FIG. 13, the planar transformer 1 has a five-layer structure. That is, the primary winding assembly includes four primary winding units 3, and the secondary winding assembly includes one secondary winding unit 4. The four primary winding units 3 are respectively formed in a first layer, a second layer, a fourth layer and a fifth layer of the five-layer structure, and the secondary winding unit 4 is formed in a third layer of the five-layer structure. Each of the first conductive sheets 31 of the four primary winding units 3 has two turns (each layer is marked with two P symbols), and the second conductive sheet 40 of the secondary winding unit 4 has one turn (this layer is marked with one S symbol). Due to this structural design, the magnetic motive force trend of the planar transformer 1 in FIG. 13 becomes completely symmetrical when compared with the magnetic motive force of the planar transformer 1 in FIG. 11, and the size of the parasitic stray capacitance is reduced.

From the above descriptions, the present disclosure provides a planar transformer and a power supply device with the planar transformer. The planar transformer of the present disclosure has the advantages of conventional planar transformers. For example, the planar transformer of the present disclosure has excellent repeatability and consistency, and the planar transformer is easy to produce. Furthermore, in the primary winding unit, the first conductive sheet is covered by the printed circuit board. Consequently, the problems of high losses and limited power capacity in conventional planar transformers due to insufficient copper foil thickness can be solved. Moreover, due to the structural design of the first outlet terminal and the second outlet terminal, the planar transformer and a power semiconductor module are suitably integrated into a DC-DC converter power module. Consequently, the overall size is reduced. The modular design of the planar transformer also simplifies the assembling process. Furthermore, the first conductive sheets of every two adjacent primary winding units and the second conductive sheet of the secondary winding unit are insulated from each other through the printed circuit boards of the two adjacent primary winding units. Consequently, the manufacturing process is simplified.

Moreover, since the cross-sectional area of the primary winding assembly of the planar transformer can be maximized, the winding space utilization is improved, and the power density is increased. Since the thickness of the first conductive sheet is also increased, the DC resistance is reduced, and the operating efficiency of the planar transformer is improved. Furthermore, by adjusting the structure and the winding method of the primary winding assembly and the secondary winding assembly of the planar transformer of the present disclosure, the magnetic motive force (MMF) and the parasitic stray capacitance are adjusted.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all modifications and similar structures.

What is claimed is:

1. A planar transformer, comprising:
a primary winding assembly comprising at least one primary winding unit, wherein each of the at least one primary winding unit comprises a printed circuit board and a first conductive sheet, and the first conductive sheet is embedded within the printed circuit board;
a secondary winding assembly comprising at least one secondary winding unit; and
a magnetic core assembly comprising at least one magnetic core, wherein at least a portion of the at least one primary winding unit and at least a portion of the at least one secondary winding unit are enclosed by the magnetic core assembly.

2. The planar transformer according to claim 1, wherein the first conductive sheet has an annular, rectangular or polygonal sheet-like structure with a notch, and the first conductive sheet is made of a conductive material.

3. The planar transformer according to claim 1, wherein the at least one primary winding unit includes a plurality of primary winding units, and the first conductive sheets of the plurality of primary winding units are connected with each other in series.

4. The planar transformer according to claim 1, wherein the at least one primary winding unit includes a plurality of primary winding units, and each of the first conductive sheets of the plurality of primary winding units comprises two first outlet terminals, wherein the first conductive sheets of the plurality of primary winding units are arranged in a same direction, and the first outlet terminals of the first conductive sheets of the plurality of primary winding units are located at a first side of the planar transformer.

5. The planar transformer according to claim 4, wherein each of the at least one secondary winding unit includes a second conductive sheet, wherein the second conductive sheet has an annular, rectangular or polygonal sheet-like structure with a notch, and the second conductive sheet is made of a conductive material.

6. The planar transformer according to claim 5, wherein the at least one secondary winding unit includes a plurality of secondary winding units, and each of the second conductive sheets of the plurality of secondary winding units comprises two second outlet terminals, wherein the second conductive sheets of the plurality of secondary winding units are arranged in a same direction, and the second outlet terminals of the second conductive sheets of the plurality of secondary winding units are located at a second side of the planar transformer, wherein the first side and the second side are two opposite sides of the planar transformer.

7. The planar transformer according to claim 5, wherein the at least one primary winding unit includes a plurality of primary winding units, wherein one of the at least one secondary winding unit is arranged between every two adjacent primary winding units, and the first conductive sheets of the two adjacent primary winding units and the second conductive sheet of the secondary winding unit are insulated from each other through the printed circuit boards of the two adjacent primary winding units.

8. The planar transformer according to claim 5, wherein the at least one primary winding unit includes four primary winding units, and the at least one secondary winding unit includes three secondary winding units, so that the planar transformer has a seven-layer structure, wherein the four primary winding units are respectively formed in a first layer, a third layer, a fifth layer and a seventh layer of the seven-layer structure, and the three secondary winding units are respectively formed in a second layer, a fourth layer and a sixth layer of the seven-layer structure, wherein each of the first conductive sheets of the four primary winding units has two turns, and each of the second conductive sheets of the three secondary winding units has one turn.

9. The planar transformer according to claim 5, wherein the at least one primary winding unit includes two primary winding units, and the at least one secondary winding unit includes one secondary winding unit, so that the planar transformer has a three-layer structure, wherein the two primary winding units are respectively formed in a first layer and a third layer of the three-layer structure, and the secondary winding unit is formed in a second layer of the three-layer structure, wherein each of the first conductive sheets of the two primary winding units has four turns, and the second conductive sheet of the secondary winding unit has one turn.

10. The planar transformer according to claim 5, wherein the at least one primary winding unit includes four primary winding units, and the at least one secondary winding unit includes one secondary winding unit, so that the planar transformer has a five-layer structure, wherein the four primary winding units are respectively formed in a first layer, a second layer, a fourth layer and a fifth layer of the five-layer structure, and the secondary winding unit is formed in a third layer of the five-layer structure, wherein each of the first conductive sheets of the four primary winding units has two turns, and the second conductive sheet of the secondary winding unit has one turn.

11. The planar transformer according to claim 1, wherein the at least one magnetic core includes two magnetic cores, and the at least one secondary winding unit includes one secondary winding unit, wherein the two magnetic cores are located on two opposite outer sides of the planar transformer, and the at least a portion of the at least one primary winding unit and the at least a portion of the at least one secondary winding unit are enclosed by the two magnetic cores collaboratively.

12. A power supply device, comprising:
an input terminal;
an output terminal;
a power factor correction device configured to receive a three-phase AC power through the input terminal;
a first planar transformer and a second planar transformer, wherein each of the first planar transformer and the second planar transformer comprises a primary winding assembly, a secondary winding assembly and a magnetic core assembly, wherein the primary winding assembly comprises at least one primary winding unit, the secondary winding assembly comprises at least one secondary winding unit, and the magnetic core assembly comprises at least one magnetic core, wherein each of the at least one primary winding unit comprises a printed circuit board and a first conductive sheet, the first conductive sheet is embedded within the printed circuit board, and at least a portion of the at least one primary winding unit and at least a portion of the at least one secondary winding unit are enclosed by the magnetic core assembly;
a main circuit board;
a primary winding connection board connected with the at least one primary winding unit of the first planar transformer and the at least one primary winding unit of the second planar transformer;
a secondary winding connection board connected with the at least one secondary winding unit of the first planar transformer and the at least one secondary winding unit of the second planar transformer;
a water-cooling heat dissipation device;
an inverter device configured to output an output DC power to the output terminal;
a first housing; and
a second housing, wherein the main circuit board, the first planar transformer, the second planar transformer, the water-cooling heat dissipation device, the power factor correction device and the inverter device are covered by the first housing and the second housing.

13. The power supply device according to claim 12, wherein in each of the first planar transformer and the second planar transformer, the at least one primary winding unit includes a plurality of primary winding units, and each of the first conductive sheets of the plurality of primary winding units comprises two first outlet terminals, wherein the first conductive sheets of the plurality of primary winding units are arranged in a same direction, the first outlet terminals of the first conductive sheets of the plurality of primary winding units are located at a first side of each of the first planar transformer and the second planar transformer, and the first outlet terminals are inserted into the primary winding connection board.

14. The power supply device according to claim 13, wherein in each of the first planar transformer and the second planar transformer, the at least one secondary winding unit comprises a second conductive sheet.

15. The power supply device according to claim 14, wherein in each of the first planar transformer and the second planar transformer, the at least one secondary winding unit includes a plurality of secondary winding units, and each of the second conductive sheets of the plurality of secondary winding units comprises two second outlet terminals, wherein the second conductive sheets of the plurality of secondary winding units are arranged in a same direction, the second outlet terminals of the second conductive sheets of the plurality of secondary winding units are located at a second side of each of the first planar transformer and the second planar transformer, and the second outlet terminals of the second conductive sheets of the plurality of secondary winding units are inserted into the secondary winding connection board, wherein the first side and the second side are two opposite sides.

16. The power supply device according to claim 14, wherein in each of the first planar transformer and the second planar transformer, the at least one primary winding unit includes four primary winding units, and the at least one secondary winding unit includes three secondary winding units, so that the planar transformer has a seven-layer structure, wherein the four primary winding units are respectively formed in a first layer, a third layer, a fifth layer and a seventh layer of the seven-layer structure, and the three secondary winding units are respectively formed in a second layer, a fourth layer and a sixth layer of the seven-layer structure, wherein each of the first conductive sheets of the four primary winding units has two turns, and each of the second conductive sheets of the three secondary winding units has one turn.

17. The power supply device according to claim 14, wherein in each of the first planar transformer and the second planar transformer, the at least one primary winding unit includes two primary winding units, and the at least one secondary winding unit includes one secondary winding unit, so that the planar transformer has a three-layer structure, wherein the two primary winding units are respectively formed in a first layer and a third layer of the three-layer structure, and the secondary winding unit is formed in a second layer of the three-layer structure, wherein each of the first conductive sheets of the two primary winding units has four turns, and the second conductive sheet of the secondary winding unit has one turn.

18. The power supply device according to claim 14, wherein in each of the first planar transformer and the second planar transformer, the at least one primary winding unit includes four primary winding units, and the at least one secondary winding unit includes one secondary winding unit, so that the planar transformer has a five-layer structure, wherein the four primary winding units are respectively formed in a first layer, a second layer, a fourth layer and a fifth layer of the five-layer structure, and the secondary winding unit is formed in a third layer of the five-layer structure, wherein each of the first conductive sheets of the four primary winding units has two turns, and the second conductive sheet of the secondary winding unit has one turn.
